(19) United States
(12) Patent Application Publication
(10) Pub. No.: US 2024/0071976 A1
(43) Pub. Date: Feb. 29, 2024

(54) SEMICONDUCTOR DEVICE WITH A POLYMER LAYER

(71) Applicant: Micron Technology, Inc., Boise, ID (US)

(72) Inventor: Wei Zhou, Boise, ID (US)

(21) Appl. No.: 17/899,574

(22) Filed: Aug. 30, 2022

(51) Int. Cl. H01L 23/00; H01L 23/29; H01L 23/31; H01L 25/065

(52) U.S. Cl. CPC H01L 24/32; H01L 23/291; H01L 23/3171; H01L 24/08; H01L 24/16; H01L 24/27; H01L 24/29; H01L 24/73; H01L 24/81; H01L 24/83; H01L 25/0657; H01L 2224/0801; H01L 2224/08055; H01L 2224/08056; H01L 2224/16014; H01L 2224/16055; H01L 2224/16148; H01L 2224/27622; H01L 2224/29011; H01L 2224/29191; H01L 2224/32013; H01L 2224/32054; H01L 2224/32058; H01L 2224/3207; H01L 2224/32145; H01L 2224/73204; H01L 2224/81203; H01L 2224/81895; H01L 2224/83009; H01L 2224/83099; H01L 2224/83896; H01L 2224/83907; H01L 2225/06513; H01L 2225/06517; H01L 2225/06524; H01L 2225/06527; H01L 2225/06541

(57) ABSTRACT

This document discloses techniques, apparatuses, and systems for a semiconductor device with a polymer layer. A semiconductor assembly is described that includes two semiconductor dies. The first semiconductor die has a first active side with first circuitry and a first back side opposite the first active side. Contact pads and a layer of polymer material are disposed at the first back side such that the layer of polymer material includes openings that expose the contact pads. The second semiconductor die has second circuitry disposed at a second active side. Interconnect structures are also disposed at the second active side such that the interconnect structures extend into the openings and couple to contact pads. A passivation layer (e.g., dielectric material) is disposed at the second active side and directly bonded to the layer of polymer material to reliably couple the two semiconductor dies.

### TECHNICAL FIELD

The present disclosure generally relates to semiconductor device assemblies, and more particularly relates to semiconductor devices with a polymer layer.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of an example semiconductor device assembly.

FIG. 2 illustrates a simplified schematic cross-sectional view of a semiconductor device assembly in accordance with an embodiment of the present technology.

FIG. 3 illustrates a simplified schematic partial plan view of a semiconductor device assembly in accordance with an embodiment of the present technology.

FIG. 4 illustrates a simplified schematic partial plan view of a semiconductor device assembly in accordance with an embodiment of the present technology.

FIGS. 5-10 illustrate simplified schematic cross-sectional views of a series of fabrication steps of semiconductor device assemblies in accordance with an embodiment of the present technology.

FIG. 11 illustrates a simplified schematic cross sectional view of a semiconductor device assembly in accordance with an embodiment of the present technology.

FIG. 12 illustrates a schematic view showing a system that includes a semiconductor device assembly configured in accordance with an embodiment of the present technology.

FIG. 13 illustrates an example method for fabricating a semiconductor device assembly in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without simultaneously increasing the size of the device. This development, however, may not be sustainable due to various challenges that arise from designing semiconductor device with high circuit density. Thus, additional techniques may be required to continue the growth in capability of semiconductor devices.

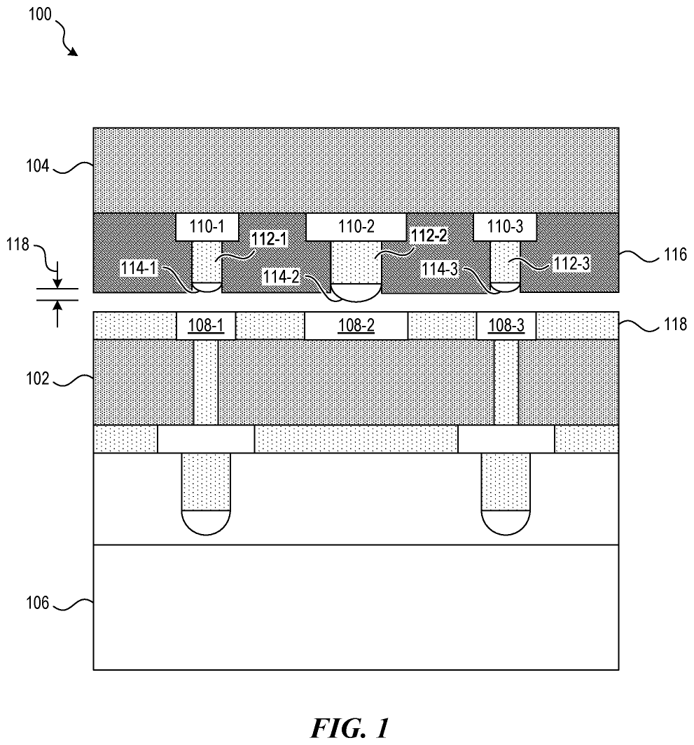

One such technique is to implement multiple semiconductor dies within a single package. These multiple dies may be stacked to increase the number of circuit elements within the package without increasing a footprint (e.g., horizontal area) of the device. Stacked semiconductor devices (e.g., three-dimensional interface (3DI) packaging solutions) are often implemented as a set of multiple semiconductor dies disposed on a semiconductor wafer. The semiconductor wafers may be thinned (e.g., to less than 100 micrometers (μm)) to reduce the vertical thickness of the stacked semiconductor devices and satisfy the spatial constraints of the electronic device in which they are implemented, for example, based on the thickness of the electronic device. These dies are then physically and electronically connected to one another to secure and communicatively couple the stacked dies. Many solutions for connecting the dies, however, may inhibit operation of the semiconductor device. One such semiconductor assembly is illustrated by way of example in FIG. 1.

As can be seen with reference to FIG. 1, a semiconductor device assembly 100 includes a semiconductor die 102 and a semiconductor die 104 mounted to a carrier substrate 106 (e.g., temporary substrate). Although illustrated as a carrier substrate that may be used to perform die-level stacking, the substrate 106 may instead be an additional die or multiple additional dies, for example, to perform wafer-level stacking (e.g., wafer-to-wafer, die-to-wafer). The die 102 may be coupled to the substrate 106 such that a back side of the die 102 (e.g., opposite an active side at which circuitry is disposed) corresponds to the upper surface of the die 102 as illustrated. The die 104 may be stacked similarly onto the die 102 such that a back side of the die 104 corresponds to the upper surface of the die 104 as illustrated.

The semiconductor die 102 and the semiconductor die 104 may include contact pads 108 (e.g., contact pad 108-1, 108-2, and 108-3) and contact pads 110 (e.g., contact pad 110-1, 110-2, and 110-3), respectively. The dies may be coupled (e.g., stacked) such that the contact pads 108 couple to the contact pads 110 through the interconnects 112 (e.g., interconnect 112-1, 112-2, and 112-3) to provide connectivity to the dies (e.g., power, ground, and I/O signals) through traces, lines, vias, and other electrical connection structures (not illustrated). The interconnects 112 may couple (e.g., electrically, communicatively, mechanically) to the contact pads 110 through solder joints composed of solder material 114 (e.g., solder material 114-1, 114-2, and 144-3). While the solder material 114 may effectively couple the dies electrically or communicatively, the solder material 114 may have insufficient strength to ensure the physical coupling of the dies. In this way, the dies may not properly stack if the coupling is not supported elsewhere.

The die 104 may include a layer of polymer material 116 that bonds to a passivation layer 118 (e.g., dielectric material) to ensure the robustness of the mechanical coupling of the dies. As illustrated in FIG. 1, the layer of polymer material 116 may be deposited on the active surface of the die 104 to which circuitry is disposed. The layer of polymer material 116 is deposited on the die 104 around the interconnects 112. The layer of polymer material 116 may be deposited at the bottom surface of the die 104 such that it covers the solder material 114. The surface of the layer of polymer material 116 may then be planarized (e.g., chemically, mechanically, or any combination of the two) to reveal the solder material 114.

In some instances, planarization of the layer of polymer material 116 may cause the solder material 114 to protrude beyond the bottom surface of the layer of polymer material 116. Moreover, various portions (solder material 114-1, 114-2, and 114-3) of the solder material 114 may react differently to planarization. For example, larger portions of the solder material used for grounding or power interconnects 114 (e.g., solder material 114-2) may resist planarization more than smaller portions (e.g., solder material 114-1 and 114-3) used for data line interconnects. Similarly, solder material 114 (e.g., particularly large portions, such as solder material 114-2) may resist planarization more than the layer of polymer material 116, for example, due to the malleability of the solder material 114. These effects may cause the solder material 114 (e.g., or portions of the solder material, as illustrated solder material 114-2) to protrude (e.g., by a protrusion measure 120) from the layer of polymer material 116, especially when different size interconnects 112 and soldering material 114 are implemented on a die (e.g., based on the purpose of the interconnect).

As die 102 and die 104 are coupled, one or more of the interconnects 112 may couple to the contact pads 108, which may cause the layer of polymer material 116 not to contact the passivation layer 118. Thus, the layer of polymer material 116 and the passivation layer 118 may not bond, and the coupling of the dies may only be supported by the solder joints coupling of the one or more interconnects 112 to the contact pads 108. As discussed above, the solder joints may be insufficient to support the stacking of the die, and thus, without the bond between the layer of polymer material 116 and the passivation layer 118, the structural integrity of the coupling may be insufficient to support the die stack. Moreover, differences in protrusion of the various solder material 114 may create voids (not shown) between the interconnects 112 and the contact pads 108, which may cause shorting or leakage between the contacts, thereby limiting or disabling interactions between the dies (e.g., power signaling, grounding, communication signaling).

In some instances, the layer of polymer material 116 may be etched (e.g., using photolithography) to open the layer of polymer material 116 and further expose the solder material 114. The planarization and etching of the layer of polymer material 116 may create variation in the surface of the layer of polymer material 116 or the solder material 114, for example, between an edge of the surface and the center of the surface. Additionally, the process for developing of the semiconductor device (e.g., stacking the dies) after the lithography has been performed may differ based on pitch (e.g., center-to-center distance between the interconnects 112). For example, portions of the die with smaller pitch (e.g., portions containing interconnects used as data lines) may be coupled to another die through different processes than portions of the die with larger pitch (e.g., portions containing interconnects used as a ground or as a power supply). For any of these reasons, the semiconductor device assembly 100 may lack robustness and scalability.

To address these drawbacks and others, various embodiments of the present application provide semiconductor device assemblies that include a first die having a layer of polymer material designed with openings that correspond to interconnects on an additional die. The layer of polymer material may be located on a die to which the interconnects bond (e.g., instead of on the same die as the interconnect). The interconnects may couple to contact pads exposed by the openings to electrically couple the dies. The layer of polymer material may similarly bond to a passivation layer located on the same die as the interconnects to structurally support the semiconductor device assembly. In doing so, a reliable, structurally robust, and scalable semiconductor device may be assembled.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a printed circuit board (PCB) or wafer-level substrate, a die-level substrate, or another die for die-stacking or 3DI applications. The substrate may be a carrier substrate (e.g., temporary substrate) to structurally support one or more dies during fabrication or assembly.

A person having ordinary skill in the relevant art will recognize that suitable steps of the methods described herein can be performed at the wafer level or at the die level. Thus, although some examples may be illustrated or described with respect to dies or wafer, the technology disclosed herein may apply to dies or wafers. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

As used herein, the terms “vertical,” “lateral,” “upper” and “lower” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

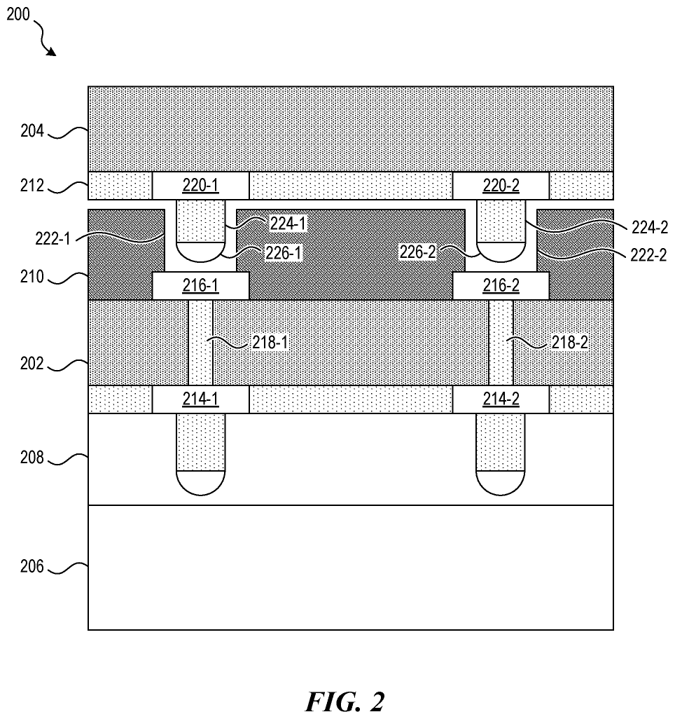

FIG. 2 is a simplified schematic cross-sectional view of a semiconductor device assembly 200 in accordance with embodiments of the present technology. The semiconductor device assembly 200 includes a semiconductor die 202 and a semiconductor die 204 mounted to a carrier substrate 206 (e.g., temporary substrate). Although illustrated as a carrier substrate that may be used to perform die-level stacking, the substrate 106 may instead be an additional die or multiple additional dies, for example, to perform die-level or wafer-level stacking (e.g., wafer-to-wafer, die-to-wafer). The die 202 may be coupled to the substrate 206 such that a back side of the die 202 (e.g., opposite an active side at which circuitry is disposed) corresponds to the upper surface of the die 202 as illustrated. The die 202 may be coupled to the substrate 206 through a temporary adhesive 208, which may later be removed. The die 204 may be stacked onto the die 202 such that a back side of the die 204 corresponds to the upper surface of the die 204, as illustrated.

The die 202 may include layer of polymer material 210 deposited (e.g., through chemical vapor deposition, physical vapor deposition, atomic layer deposition, spin coating, and/or other suitable techniques) at the back side. The layer of polymer material 210 may couple to a passivation layer 212 (e.g., a dielectric material) located at the active surface of the die 204. The passivation layer 112 may be deposited through any suitable technique, including oxidation or any of the deposition techniques detailed above. The layer of polymer material 210 and the passivation layer 212 may include mating surfaces that bond to one another when die 202 and die 204 are coupled to structurally support the semiconductor device assembly 200.

The die 202 may include one or more contact pads, for example, conductive pads that couple directly or indirectly to internal or external traces, vias, lines, and other electrical connection structures to provide functionality to the dies (e.g., power, ground, input/output (I/O) signals). As illustrated, the die 202 includes contact pads 214 (e.g., contact pad 214-1 and 214-2) at the active side and contact pads 216 (e.g., contact pad 216-1 and contact pad 216-2) at the back side. The die 202 includes through-silicon vias (TSVs 218) (e.g., TSV 218-1 and 218-2) to couple the contact pads 214 to the contact pads 216. The TSVs 218 may be implemented as conductive structures (e.g., interconnects) that pass through the die or substrate thereon. In this way, circuitry coupled to the contact pads 214 may directly communicate with circuitry coupled to the contact pads 216 without electrically routing through circuitry in the die 202.

The die 204 may similarly include one or more contact pads implemented at the active side or the back side. As illustrated, the die 204 includes contact pads 220 (e.g., contact pad 220-1 and 220-2) implemented at the active side and coupled to the contact pads 216 through interconnects 224 (e.g., interconnect 224-1 and 224-2). The contact pads 216 are exposed to the interconnects 224 through openings 222 (e.g., opening 222-1 and 222-2) recessed in the layer of polymer material 210. The openings 222 may correspond to the interconnects 224 such that when the dies are coupled, the interconnects 224 are coupled to the contact pads 216 through the openings 222. For example, the opening 222-1 may correspond to the interconnect 224-1, and the opening 222-2 may correspond to the interconnect 224-2.

The interconnects 224 may couple to the contact pads 216 through one or more intermediary metal. As illustrated, the interconnects 224 couple to the contact pads 216 through solder joints created from solder material 226 (e.g., solder material 226-1 and 226-2) located at a distal end (e.g., a lateral surface farthest from the contact pads 220) of the interconnects 224. The solder joints may electrically and physically couple the interconnect to the contact pads 216. As the dies are coupled, the solder material 226 may contact the contact pad 216 and the interconnect 224 to enable interaction (e.g., power transfer, grounding, I/O signaling) between the dies. Alternatively, the interconnects 224 may couple to the contact pads 216 without an intermediary metal and instead be a solid structure, for example, a solid copper structure resulting from Cu—Cu diffusion bonding.

The layer of polymer material 210 and the interconnects 224 may be designed such that a bonding surface of the layer of polymer material 210 (e.g., an upper surface of the layer of polymer material as illustrated) contacts a bonding surface of the passivation layer 212 (e.g., a lower surface of the passivation layer as illustrated) when the dies are coupled. The layer of polymer material 210 may be deposited at the back side of the die 202, optionally planarized (e.g., chemically, mechanically, or any combination of both) down to an appropriate thickness (e.g., between 2 to 40 microns), and patterned (e.g., etched to create the openings 222) such that the interconnects 224 or the solder material 226 thereon contact the contact pads 216 and the layer of polymer material 210 contacts the passivation layer 212 when the dies are coupled.

In some implementations, the location of the layer of polymer material 210 on a separate die than the interconnects 224 enables the layer of polymer material 210 to be formed (e.g., deposited, planarized, and etched) independent of the interconnects 224 or the solder material 226 thereon which may limit inconsistencies in the design based on different materials tendency to resist planarization. For example, the solder material 226 may not protrude from the layer of polymer material 210, given that the interconnects 224 and the solder material 226 are not planarized during a same planarization process (e.g., as described with reference to FIG. 1). In this way, the bonding of the interconnects 224 to the contact pads 216 may not prevent the layer of polymer material 210 and the passivation layer 212 from bonding at the bonding surface and physically coupling the dies to structurally support the semiconductor device assembly 200.

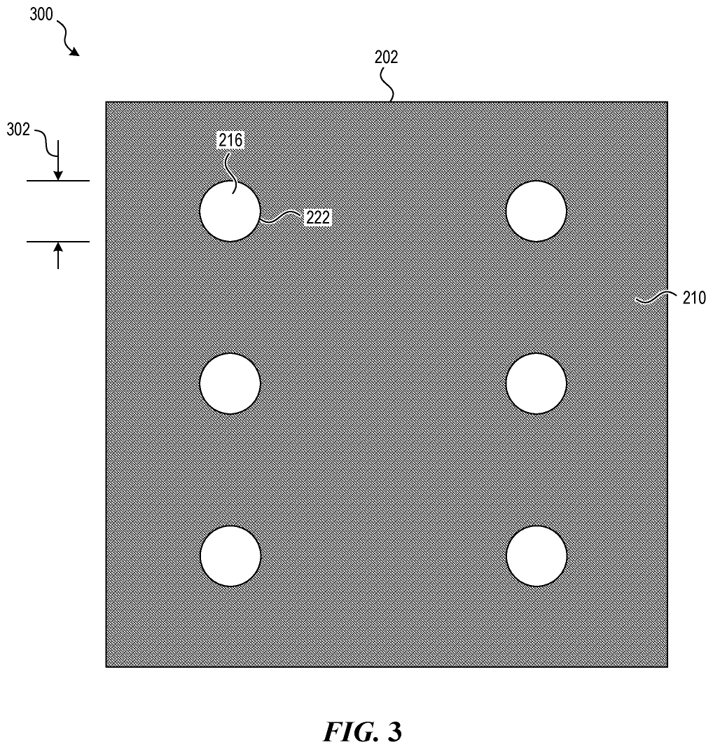

FIG. 3 illustrates a simplified schematic partial plan view of a semiconductor device assembly 300 in accordance with embodiments of the present technology. FIG. 3 may correspond to a top view (e.g., based on the configuration in FIG. 2) of the semiconductor die 202 after the layer of polymer material 210 has deposited at the back side. The surface of the layer of polymer material 210 may represent a bonding surface where the layer of polymer material 210 bonds to the passivation layer (e.g., the passivation layer 212 of FIG. 2).

The layer of polymer material 210 may be deposited as a layer of polymer protruding from the back side of the semiconductor die 202. The layer of polymer material 210 may be patterned to create openings 222 extending completely therethrough to expose the contact pads 216 such that the interconnects (e.g., interconnects 224 of FIG. 2) may couple to them to provide various functionality (e.g., enable power transfer, grounding, I/O communications) to the semiconductor device assembly 300. The openings 222 may be implemented with circular or elliptical cross sections to match the pillar-shaped interconnects. The openings 222 may be formed in the layer of polymer material 210 through etching, for example, using photolithography. Alternatively or additionally, the layer of polymer material 210 may be deposited around a mask (e.g., of photoresist or the like), which may later be removed, to create the openings 222.

The openings 222 may be implemented with a particular width along an axis coplanar with the back side of the die 202 (e.g., the plane shown in FIG. 3). For example, the openings 222 are implemented with a width dimension 302. Any one of the openings may have a width the same as or different from the width dimension 302. The width of the openings 222 may be smaller than a width of the contact pads 216 along a same axis or coplanar axis (e.g., an axis coplanar with the plane shown in FIG. 3). In this way, the layer of polymer material 210 may be implemented such that it contacts (e.g., overlaps, protrudes from) at least a portion of a contact surface of the contact pads 216 (e.g., the surface shown in FIG. 3, the upper surface with respect to the orientation shown in FIG. 2). As illustrated in FIG. 3 for example, the contact pads 216 have a rectangular shape but from the top view shown they appears circular because the openings 22 overlap a portion of the contact pads 216.

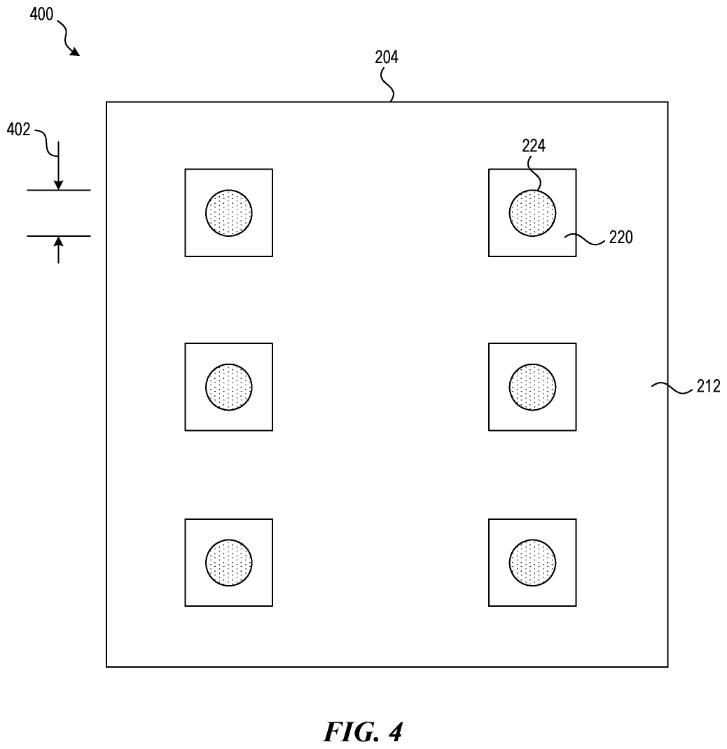

FIG. 4 illustrates a simplified schematic cross-sectional view of a semiconductor device assembly 400 in accordance with embodiments of the present technology. FIG. 4 may correspond to a bottom view (e.g., based on the configuration in FIG. 2) of the semiconductor die 204 after the passivation layer 212 has deposited at the active side. The surface of the passivation layer 212 may represent a bonding surface where the layer of polymer material (e.g., the layer of polymer material 210 of FIG. 2) bonds to the passivation layer 212.

The passivation layer 212 may be deposited or formed at the active side of the semiconductor die 204 through any appropriate technique, for example, passivation, chemical vapor deposition, physical vapor deposition, atomic layer deposition, or spin coating. The passivation layer 212 may be created by oxidizing a layer of die 204 or depositing a material at the die 204. The passivation layer 212 may include a dielectric material, for instance, a silicon material such as silicon dioxide (SiO₂), silicon nitride (SiN or Si₃N₄), silicon carbide (SiC), silicon carbon nitride (SiCN), etc. A bonding surface of the passivation layer 212 may be coplanar or nearly coplanar with a contact surface of the contact pads 220.

The contact pads 220 may be implemented at the surface of the die 204. Interconnects 224 may contact the contact pads 220 to electrically couple the interconnects 224 to the contact pads 220. The interconnects 224 may be pillar-shaped (e.g., having a circular or elliptical cross section) and protrude from the surface of the die 204 or the passivation layer 212. The interconnects 224 may be implemented with a width dimension 402 along an axis coplanar with a plane parallel to the active side (e.g., the plane shown in FIG. 4). The width dimension 402 may be less than a width dimension of the openings (e.g., the width dimension 302 shown in FIG. 3) such that space is present between the interconnects 224 and the openings (e.g., the openings 222) when the dies are coupled and the interconnects 224 are inserted into the openings.

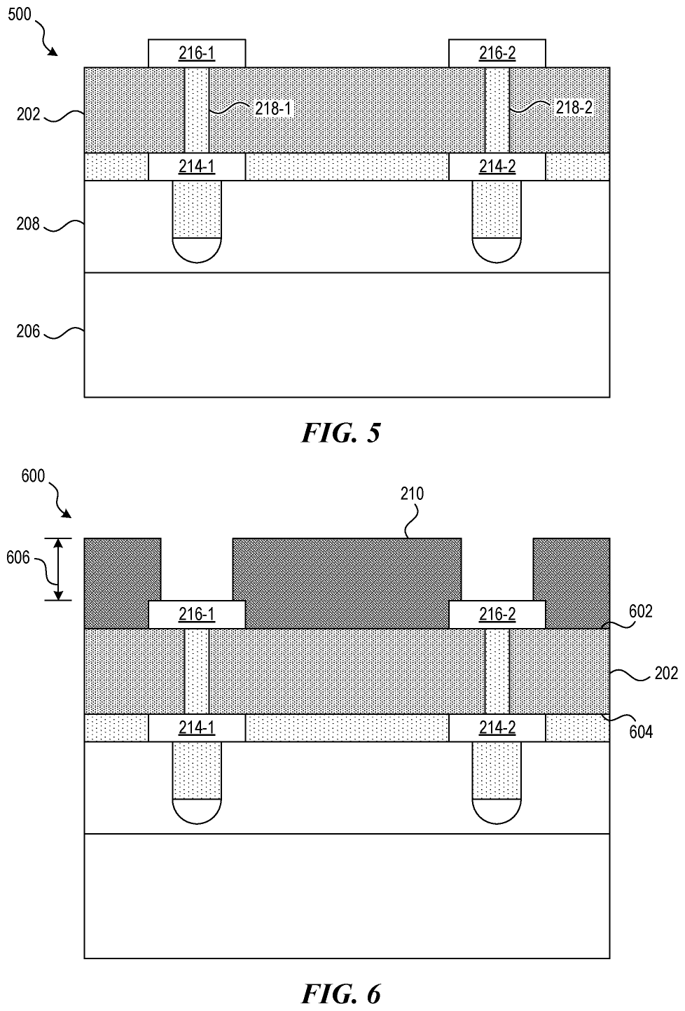

FIGS. 5 through 10 illustrate simplified schematic cross-sectional views of a semiconductor device assembly at selected stages in a manufacturing method in accordance with an embodiment of the present technology. As illustrated in FIG. 5, the method can include a stage 500 for providing the die 202. The die 202 can include contact pads 214 and contact pads 216 (e.g., solid metal structures for providing electrical connections to circuits within the die 202) protruding below a die lower surface and above a die upper surface, respectively. Contact pads 214 and contacts pads 216 may be coupled through TSVs 218 extending entirely through the die 202.

The die 202 may be coupled to a carrier substrate 206 (e.g., temporary wafer) through a temporary adhesive to support the die 202 during development or assembly. For example, silicon on which the die 202 is implemented may be thinned (e.g., to a thickness smaller than 100 micrometers (μm)) such that the silicon may not support the development of the die 202 or the stacking of multiple dies (e.g., through die-level stacking). To compensate for this deficiency, the die 202 may be temporarily coupled to a thicker carrier substrate 206. The die 202 may be developed or multiple dies may be stacked while the die 202 is mounted on the carrier substrate 206. The substrate 206 may then be removed once the semiconductor assembly is ready to be packaged and shipped. Although illustrated with a temporary substrate 206, the techniques may also be applied for wafer-level or die-level stacking using the die 202 developed on a thicker (e.g., non-thinned) substrate.

As illustrated in FIG. 6, the method can include a stage 600 for depositing a layer of polymer material 210 on a back side of the die 202. The die 202 can include a back side 602 opposite an active side 604 on which circuitry is disposed. Contact pads 214 may be disposed at the active side 604, and contact pads 216 may be disposed at the back side 602.

Layer of polymer material 210 may be deposited at the back side 602 to be used to couple the die 202 to an additional die. The layer of polymer material 210 may be deposited through any appropriate technique (e.g., chemical vapor deposition, physical vapor deposition, atomic layer deposition, spin coating) to create a continuous layer of polymer (e.g., polyimide (PI), polybenzoxazole (PBO), penzocyclobuten (BCB), epoxy, or plastic based materials) protruding from the back side 602 of the die 202. The layer of polymer material 210 may then be planarized through chemical methods, mechanical methods, or both. The planarized layer of polymer material 210 may protrude from the back side 602 of the die 202.

Openings 222 may be formed in the layer of polymer material 210, for instance, by etching the layer of polymer material 210 to create a particular pattern. The openings 222 may correspond to interconnects on an additional die to which the die 202 couples. Contact pads 216 may be exposed through the openings 222 to enable interconnects on the additional die to be inserted into the openings 222 and coupled to the contact pads 216. A width of the openings 222 may be smaller than a width of the contact pads 216 such that the layer of polymer material 210 contacts at least a portion of a contact surface (e.g., upper surface) of the contact pads 216. The depth of the openings 222 (e.g., from a bonding surface of the layer of polymer material 210) may be measured by a depth 606, which may be designed to enable the interconnects to be fully inserted into the openings 222. The depth 606 may equal a thickness of the layer of polymer material 210 at the openings 222, for example, when the contact pads 216 are flush with the surface of the die 202. Alternatively, the depth 606 may differ from the thickness of the layer of polymer material 210 at the openings 222 when the contact pads 216 are elevated from the surface of the die 202. Once the openings 222 have been recessed in the layer of polymer material 210, an additional die may be mated with the die 202 to communicatively couple the dies and enable the layer of polymer material 210 to bond with a passivation layer of the additional die.

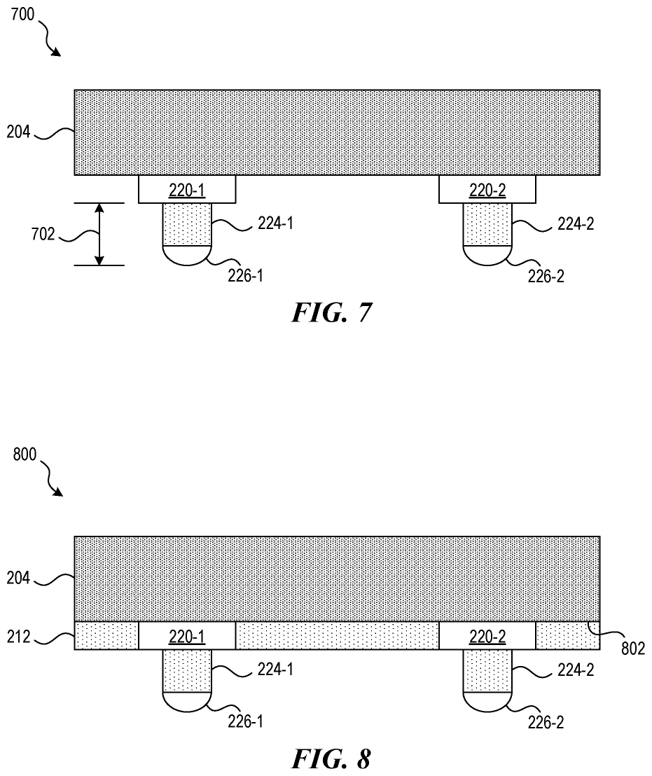

As illustrated in FIG. 7, the method can include a stage 700 of providing an additional semiconductor die 204. The die 204 can include contact pads 220 at the lower surface, which may be an active side of the die 204 on which circuitry is implemented. The contact pads 220 may protrude from a lower surface of the die 204, and interconnects 224 may extend from the contact pads 220. The interconnects 224 may couple to a solder material 226 at a distal end of the interconnects 224. The solder material 226 may be implemented as a bump, ball, cap, or any other appropriate shape.

As illustrated, the interconnects 224 may protrude from the active side of the die 204 or the passivation layer 212 by a protrusion measure 702. The protrusion measure 702 may measure the length (e.g., in the vertical dimension as illustrated) of the interconnects 224 or the interconnects 224 and the solder material 226 from a surface at the active side of the die 204 (e.g., a bonding surface of the passivation layer 212). The protrusion measure 702 may be less than or equal to a depth of the openings in which the interconnects 224 are inserted (e.g., depth 606 of openings 222 illustrated in FIG. 6). In some instances, the protrusion measure 702 may be the same as the depth of the openings to enable the solder material 226 to contact the contact pads to which the interconnects 224 are coupled (e.g., contact pads 216 of FIG. 6) when inserted in the openings, while still enabling a layer of polymer material (e.g., layer of polymer material 210 of FIG. 6) to couple to the die 204.

As illustrated in FIG. 8, the method can include a stage 800 for depositing a passivation layer 212 at a surface of the die 204. The passivation layer 212 may be deposited at a same side as the contact pads 220 and the interconnects 224. The deposition may be created by oxidizing a layer of the die 204 or depositing a material at the die 204. The deposition can be performed using any appropriate technique, including chemical vapor deposition, physical vapor deposition, atomic layer deposition, or spin coating. The passivation layer 212 may be deposited with a particular thickness, for example, the thickness may be defined such that a bonding surface (e.g., a lower surface as illustrated) may be roughly coplanar with a contact surface (e.g., a lower surface as illustrated) of the contact pads 220.

The passivation layer 212 may be composed of any number of materials. In some instances, the passivation layer 212 may be a silicon-based material. For example, the passivation layer 212 may include silicon dioxide (SiO₂) or silicon nitride (Si₃Ni₄). These materials may be created by depositing oxygen or nitrogen at the surface of the die 204. Alternatively, the passivation layer 212 may be created by oxidizing (e.g., after heating) an existing layer (e.g., silicon layer) of the die 204. In this implementation, the oxidization may occur prior to the forming of the contact pads 220, in contrast to the order of operations shown in FIGS. 7 and 8. The passivation layer 212 may be etched to form the contact pads 220 such that the contact pads 220 may still be flush with the upper surface of the passivation layer 212. The passivation layer 212 may be bonded to a layer of polymer material on a die to which the die 204 is bonded (e.g., layer of polymer material 210 of die 202 illustrated in FIG. 6).

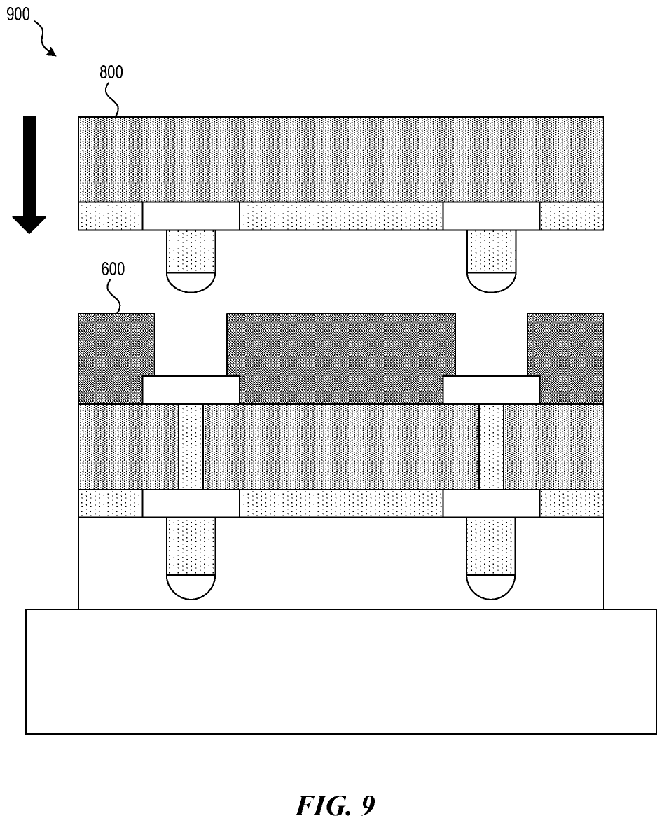

As illustrated in FIG. 9, the method may include a stage 900 for aligning the die 202 and the die 204. The stage 900 may represent a step for aligning the semiconductor assemblies illustrated in FIGS. 6 and 8. The die 204 may be positioned to be stacked onto the die 202. To do so, the interconnects 224 may be aligned with the openings 222 (e.g., interconnect 224-1 aligns with opening 222-1 and interconnect 224-2 aligns with opening 222-2).

In some instances, plasma may be applied to the bonding surface of the layer of polymer material 210 or the bonding surface of the passivation layer 212. The plasma may activate the layer of polymer material 210 or the passivation layer 212 to enable the materials to be bonded. In aspects, the plasma may cause the layer of polymer material 210 or the passivation layer 212 to become hydrophilic, thereby enabling a hydrophilic bond between the materials. The hydrophilic bond may be used as a temporary bond before the dies are permanently bonded. The plasma may additionally or alternatively be applied to the solder material 226 to remove an oxidization and enable the solder material 226 to be easily bonded (e.g., with less pressure or heat required).

The die 204 may be lowered onto the die 202 such that the solder material 226 contacts the contact pads 216 and the layer of polymer material 210 contacts the passivation layer 212. Force may be applied to the upper surface of the die 202 to couple the dies. The solder material 226 may electrically couple the dies through the contact pads 220, the interconnects 224, and the contact pads 216. The layer of polymer material 210 and the passivation layer 212 may bond (e.g., temporarily or permanently) to mechanically couple the dies and structurally support the semiconductor device assembly. Once aligned, the semiconductor device assembly may be permanently bonded to prepare for further packaging and distribution.

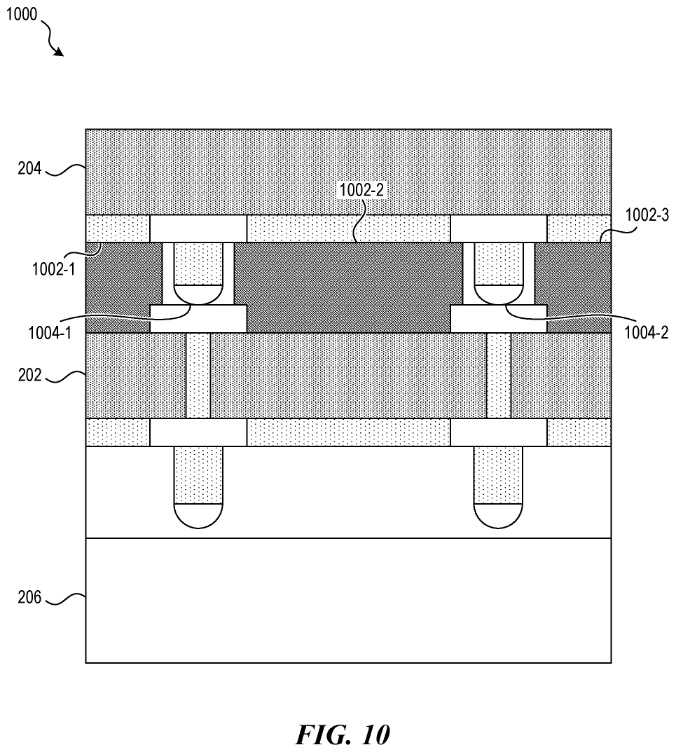

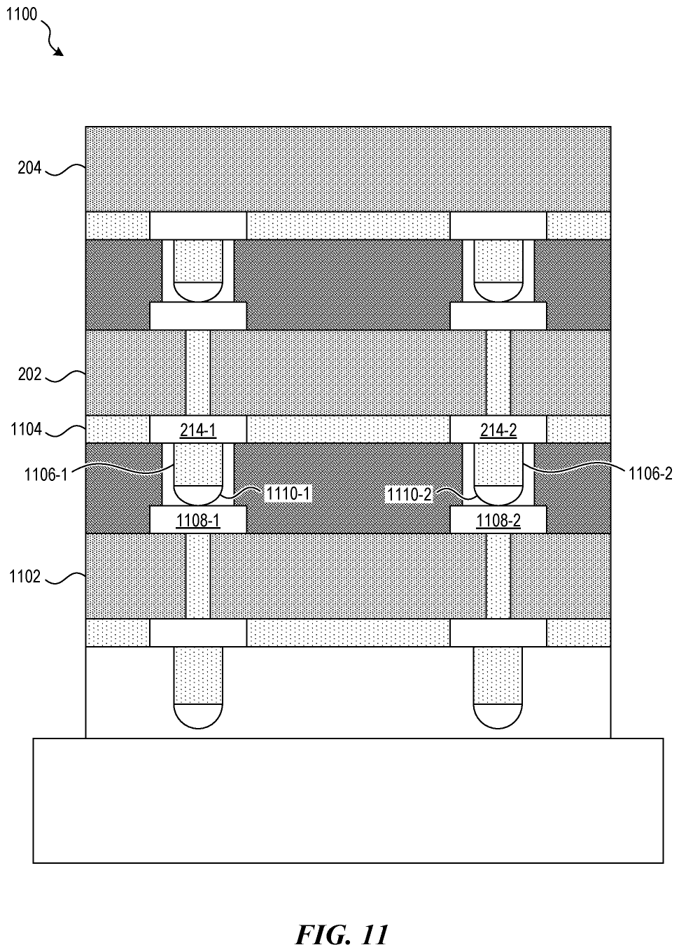

As illustrated in FIG. 10, the method may include a stage 1000 for bonding the die 202 and the die 204. Once aligned, there may be multiple bonding surfaces at which the die 202 may couple to the die 204. For example, the layer of polymer material may couple to the passivation layer at the bonding surface 1002. The bonding surface 1002 may be partitioned by the interconnects and the openings to create distinct portions of the bonding surface 1002 (e.g., bonding surface 1002-1, 1002-2, and 1002-3). Direct bonds may be created at the bonding surface 1002 by exposing the dies to a bonding process which may include creating a vacuum condition or filling the space with inert gas, heating the structures, pressing the structures together, or a combination thereof.

The interconnects and the contact pads may similarly be bonded once aligned. The interconnects may couple to the contact pads at the bonding surface 1004. For example, the interconnects and the contact pads may be bonded through an intermediary metal, as illustrated, solder (e.g., a solder cap). Alternatively, the electrical contacts may be bonded through a diffusion bonding process (e.g., Cu—Cu diffusion bonding) that includes a solid-state welding process for joining metals based on solid-state diffusion. The bond between the interconnects and the contact pads may be created through a similar bonding process as the layer of polymer material and the passivation layer, which may include creating a vacuum condition or filling the space with inert gas, heating the structures, pressing the structures together, or a combination thereof.

The bonded dies (e.g., in a stacked die assembly) may be coupled electrically through the interconnects and the contact pads and mechanically through the layer of polymer material and the passivation layer. Space (e.g., filled with air or another material) may be present between the interconnects and the layer of polymer material due to the relative differences between the width of the openings and the width of the interconnects. In this way, the interconnects may not directly contact the layer of polymer material, thereby elimination possible interference between the materials.

After the dies have been bonded, the carrier substrate 206 may be removed from the stacked dies through any number of methods, including using chemicals, heat, or force to separate the adhesive coupling the dies to the temporary substrate. Alternatively, additional dies may be stacked onto the stacked die assembly before the carrier substrate is separated, as illustrated in FIG. 11. The stacked die assembly may then be assembled on a permanent substrate, for example, a PCB. The stacked die assembly may be at least partially encapsulated by an encapsulant (e.g., housing). The encapsulant may act as a protecting covering for the dies to prevent damage from contact, radiation, moisture, and so on. The encapsulant may enclose one or more sets of semiconductor dies assembled in multiple semiconductor device assemblies or a single semiconductor device assembly.

FIG. 11 illustrates a simplified schematic cross sectional view of a semiconductor device assembly 1100 in accordance with an embodiment of the present technology. The semiconductor device assembly 1100 may correspond to the semiconductor device assembly 200 illustrated in FIG. 2 coupled to an additional semiconductor die 1102. As illustrated, the semiconductor device assembly 1100 includes a stack of three dies, specifically, the die 1102 stacked on the die 204, which is stacked on the die 202. It should be appreciated, however, that a semiconductor device assembly may include more or less dies than illustrated, and these dies may be assembled onto the semiconductor device using techniques similar to those described herein. The semiconductor device assembly 1100 may be assembled onto the carrier substrate 206, which may later be removed from the stack of semiconductor dies.

Contact pads 1104 (e.g., contact pad 1104-1 and 1104-2) are disposed at a back side (e.g., top surface as illustrated) of the die 204. The contacts pads 1104 may couple to TSVs within the die 204 to communicate with one or more other dies within the stack. The additional die 1102 may be assembled onto the die 204 such that contact pads 1106 (e.g., contact pad 1106-1 and 1106-2) couple to the contact pads 1104 through the interconnects 1108 (e.g., interconnect 1108-1 and 1108-2).

Layer of polymer material 1110 may be deposited at the back side of the die 204 to bond to a passivation layer 1112 on the die 1102. The layer of polymer material 1110 and the passivation layer 1112 may be deposited using similar techniques to those described with reference to layer of polymer material 210 and passivation layer 212 of FIGS. 5 through 10. The die stack may be bonded such that the layer of polymer material 1110 bonds to the passivation layer 1112 and the interconnects 1108 bond to the contact pads 1104.

The die stack may initially be assembled through temporary bonding instead of immediately creating permanent bonds between the dies. For example, the dies may be exposed to a plasma prior to being stacked. The plasma may create a bonding surface on the die that has a particular property (e.g., a hydrophilic property) that enables a temporary bond to form between contact surfaces. These temporary bonds may be formed in less extreme conditions than permanent bonds, for instance, at room temperature. The die stack or a portion of the die stack, may be assembled using these temporary bonds without the need for permanent bonding.

Once the die stack or the portion of the die stack is assembled using temporary bonds, a permanent bonding process may be performed to create permanent bonds within the semiconductor device assembly 1100. In some instances, the permanent bonds may be stronger than the temporary bonds (e.g., require a greater force or higher heat to separate the bond). The permanent bonding process may include vacuum condition or filling the space with inert gas, heating the structures, pressing the structures together, or a combination thereof. The permanently bonded semiconductor device assembly may then be packaged and implemented within any suitable device.

Although in the foregoing example embodiment semiconductor device assemblies have been illustrated and described as including a particular number of semiconductor dies, in other embodiments assemblies can be provided with more or less semiconductor dies. For example, the two-die semiconductor devices illustrated in FIGS. 2, 9, and/or 10 could be replaced with, e.g., a vertical stack of semiconductor devices, a plurality of semiconductor devices, mutatis mutandis.

In accordance with one aspect of the present disclosure, the semiconductor devices illustrated in the assemblies of FIGS. 2-11 could be memory dies, such as dynamic random-access memory (DRAM) dies, NOT-AND (NAND) memory dies, NOT-OR (NOR) memory dies, magnetic random-access memory (MRAM) dies, phase change memory (PCM) dies, ferroelectric random-access memory (FeRAM) dies, static random-access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

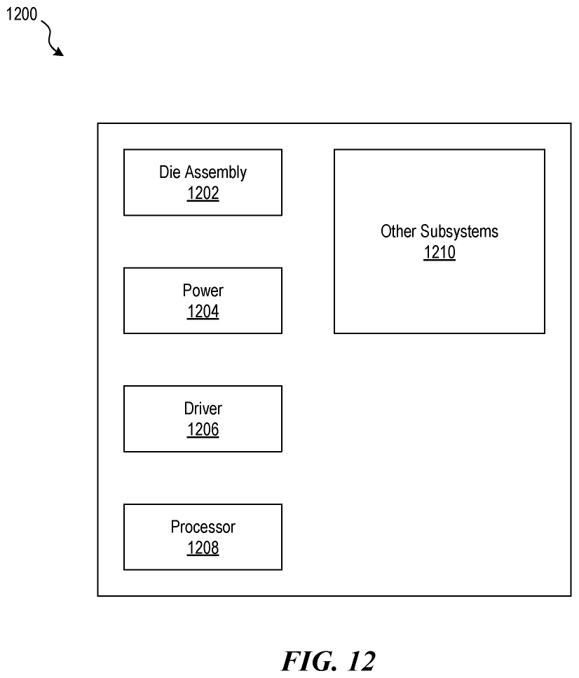

Any one of the semiconductor devices and semiconductor device assemblies described above with reference to FIGS. 2-11 can be incorporated into any of a myriad of larger and/or more complex systems, a representative example of which is system 1200 shown schematically in FIG. 12. The system 1200 can include a semiconductor device assembly 1202 (e.g., or a discrete semiconductor device), a power source 1204, a driver 1206, a processor 1108, and/or other subsystems or components 1110. The semiconductor device assembly 1202 can include features generally similar to those of the semiconductor devices described above with reference to FIGS. 2-11. The resulting system 1200 can perform any of a wide variety of functions, such as memory storage, data processing, and/or other suitable functions. Accordingly, representative systems 1200 can include, without limitation, hand-held devices (e.g., mobile phones, tablets, digital readers, and digital audio players), computers, vehicles, appliances and other products. Components of the system 1200 may be housed in a single unit or distributed over multiple, interconnected units (e.g., through a communications network). The components of the system 1200 can also include remote devices and any of a wide variety of computer-readable media.

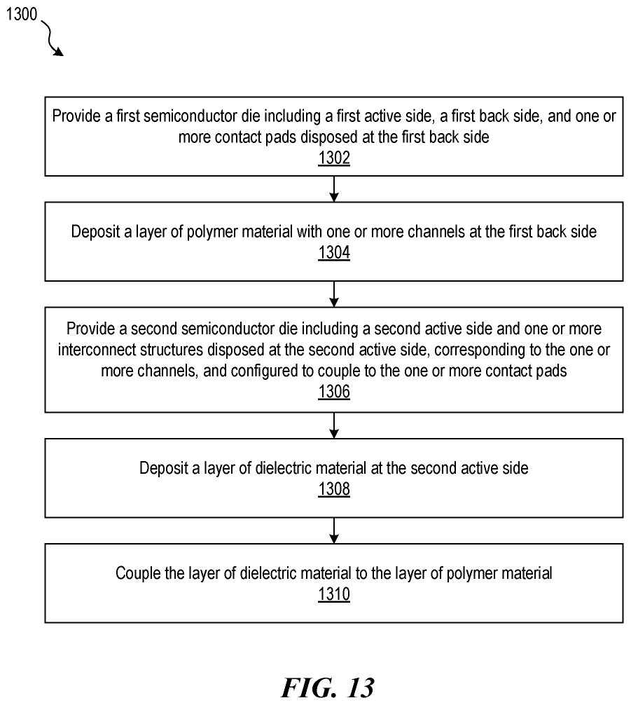

FIG. 13 illustrates an example method 1300 for fabricating a semiconductor device assembly in accordance with an embodiment of the present technology. The method 1300 may, for illustrative purposes, be described with respect to features, components, or elements of FIGS. 2-12. Although illustrated in a particular configuration, one or more operations of the method 1300 may be omitted, repeated, or reorganized. Additionally, the method 1300 may include other operations not illustrated in FIG. 13, for example, operations detailed in one or more other method described herein.

At 1302, a first semiconductor die 202 is provided. The first semiconductor die 202 may include an active side 604 containing circuitry, a back side 602 opposite the active side 604, and one or more contact pads 216 disposed at the back side 602.

At 1304, a layer of polymer material 210 may be deposited at the back side 602 of the die 202. The layer of polymer material 210 may include one or more openings 222 recessed in the layer of polymer material 210 and corresponding to interconnects 224 on a second die 204. The openings 222 may be etched in the layer of polymer material 210, for instance, through photolithography. A bonding surface of the layer of polymer material 210 may be planarized using chemical methods, mechanical methods, or a combination of both.

At 1306, a second semiconductor die 204 is provided. The second semiconductor die 204 may include an active side 802 to which circuitry is disposed. One or more interconnects 224 may be disposed at the active side 802. The interconnects 224 may correspond to the openings 224 on die 202. The interconnects may be configured to couple to the contact pads 216, which may be exposed through the openings 222.

At 1308, a passivation layer 212 may be deposited at the active side 802 of the die 204. The passivation layer 212 may include a dielectric material. The passivation layer 212 may be deposited (e.g., grown) on the active side 802 of the die 204 through oxidization or through deposition of a reactant material using any number of techniques (e.g., chemical vapor deposition, physical vapor deposition, atomic layer deposition, or spin coating).

At 1310, the passivation layer 212 may be coupled to the layer of polymer material 210. During coupling, respective interconnects of the interconnects 224 may couple to respective contact pads of the contact pads 216. The interconnects 224 may couple to the contact pads 216 through an intermediary metal, for example, the solder material 226. The passivation layer 212 may bond to the layer of polymer material 210 through a direct bond without an intermediary metal. In some instances, coupling the dies may include coupling the layer of polymer material 210 to the passivation layer 212 through a temporary bond. The layer of polymer material 210 or the passivation layer 212 may be treated with a plasma that provides hydrophilic properties to the materials. The layer of polymer material 210 may then be coupled to the passivation layer 212 to create a temporary hydrophilic bond. In some implementations, the temporary hydrophilic bond may be formed in less strenuous conditions than a permanent bond, for example, at room temperature.

In aspects, the temporary bond may be used to assemble the semiconductor device prior to forming a permanent bond between the dies. A permanent bond may be formed after the layer of polymer material 210 is coupled to the passivation layer 212 through the temporary hydrophilic bond. For example, the die 204 or the die 202 may be heated, and pressure may be applied to one or more of the dies to permanently couple the dies after the temporary bond has formed. The bonding may include coupling the interconnects 224 to the contact pads 216 (e.g., through the solder material 226) and coupling the layer of polymer material 210 to the passivation layer 212 (e.g., through a direct bond). Once coupled, the first semiconductor die 202 and the second semiconductor die 204 may operate alone or in combination with other semiconductor dies to provide functionality to a device in which it is implemented. In this way, performing the method 1300 may fabricate a robust and scalable semiconductor device.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor die including:
a first active side comprising first circuitry;
a first back side opposite the first active side;
one or more contact pads at the first back side; and
a layer of polymer material disposed over the first back side, the layer of polymer material having one or more openings exposing the one or more contact pads; and
a second semiconductor die including:
a second active side comprising second circuitry;
a layer of dielectric material at the second active side and bonded directly to the layer of polymer material; and
a one or more interconnect structures projecting from the second active side, each respective interconnect structure of the one or more interconnect structures extending into a respective opening of the one or more openings and coupled to a respective contact pad of the one or more contact pads,
wherein each of the one of more interconnect structures is laterally spaced apart from the layer of polymer material.

2. The semiconductor device assembly of claim 1, wherein:
the one or more openings include a first width dimension along an axis coplanar with the first back side;
the one or more interconnect structures include a second width dimension along an axis coplanar with the second active side; and
the first width dimension is greater than the second width dimension.

3. The semiconductor device assembly of claim 2, wherein:
the one or more contact pads include a third width dimension along the axis coplanar with the first back side; and
the third width dimension is greater than the first width dimension.

4. The semiconductor device assembly of claim 1, wherein the layer of polymer material directly contacts a portion of the one or more contact pads.

5. The semiconductor device assembly of claim 1, wherein:
the one or more openings extend completely through a thickness of the layer of polymer material;
the one or more interconnect structures project from the second active side by a length; and
the thickness is greater than or equal to the length.

6. The semiconductor device assembly of claim 1, wherein the interconnect structure is a pillar.

7. The semiconductor device assembly of claim 1, wherein each respective interconnect structure couples to the respective contact pad through a solder joint.

8. The semiconductor device assembly of claim 1, wherein the layer of dielectric material comprises silicon oxide, silicon nitride, silicon carbide, silicon carbon nitride, or a combination thereof.

9. The semiconductor device assembly of claim 1, wherein the layer of polymer materials comprises polyimide, polybenzoxazole, penzocyclobuten, epoxy, or plastic based materials.

10. The semiconductor device assembly of claim 1, further comprising an encapsulant that at least partly encapsulates the first semiconductor die and the second semiconductor die.

11. The semiconductor device assembly of claim 1, wherein:
the second semiconductor die includes:
a second back side opposite the second active side;
one or more additional contact pads at the second back side
an additional layer of polymer disposed over the second back side, the layer of polymer material having one or more additional openings exposing the one or more additional contact pads; and
one or more through-silicon vias electrically coupling the one or more additional contact pads to the one or more interconnect structures; and
the semiconductor device assembly further comprises:
a third die including:
a third active side comprising third circuitry; and
one or more additional interconnect structures extending into the one or more additional openings and coupled to the one or more additional contact pads.

12. A method of making a semiconductor device assembly, comprising:
providing a first semiconductor die including:
a first active side comprising first circuitry;
a first back side opposite the first active side;
one or more contact pads disposed at the first back side; and
a layer of polymer material at the first back side, the layer of polymer material having one or more openings exposing the one or more contact pads;
providing a second semiconductor die including:
a second active side comprising second circuitry;
one or more interconnect structures projecting from the second active side, each respective interconnect structure of the one or more interconnect structures extending into a respective opening of the one or more opening and coupling to a respective contact pad of the one or more contact pads; and
a layer of dielectric material at the second active side; and
directly bonding the layer of dielectric material to the layer of polymer material.

13. The method of claim 12, further comprising coupling each respective interconnect structure to the respective contact pad through a solder joint.

14. The method of claim 12, wherein the layer of dielectric material comprises silicon oxide, silicon nitride, silicon carbide, silicon carbon nitride, or a combination thereof.

15. The method of claim 12, further comprising:
coupling the layer of polymer material to the layer of dielectric material through a temporary hydrophilic bond;
heating the second semiconductor die after coupling layer of polymer material to the layer of dielectric material through the temporary hydrophilic bond to couple each respective interconnect structure to the respective contact pad and to form a direct bond having a larger minimum separating force than the temporary hydrophilic bond.

16. The method of claim 12, further comprising:
treating the layer of polymer material, the layer of dielectric material, or both with plasma; and
coupling the layer of polymer material and the layer of dielectric material after treating the layer of polymer material, the layer of dielectric material, or both with plasma.

17. The method of claim 12, further comprising coupling the layer of dielectric material to the layer of polymer material at room temperature.

18. The method of claim 12, further comprising etching the layer of polymer material to create the one or more openings.

19. A semiconductor device assembly, comprising:
a first semiconductor die including:
a first active side comprising first circuitry;
a first back side opposite the first active side;
one or more contact pads at the first back side; and
a layer of polymer material disposed over the first back side, the layer of polymer material having one or more openings exposing the one or more contact pads, each respective opening having a respective first width dimension along an axis coplanar with the first back side; and
a second semiconductor die including:
a second active side comprising second circuitry; and
one or more interconnect structures projecting from the second active side, each respective interconnect structure of the one or more interconnect structures extending into a respective opening of the one or more openings and coupled to a respective contact pad of the one or more contact pads, each respective interconnect structure having a second respective width dimension along an axis coplanar with the second active side, the second respective width dimension less than the first respective width dimension.

20. The semiconductor device assembly of claim 19, wherein each respective interconnect structure couples to the respective contact pad through a solder joint.
